(19) United States
(12) Patent Application Publication
(10) Pub. No.: US 2002/0142526 A1
(43) Pub. Date: Oct. 3, 2002

(54) Structures and methods to minimize plasma charging damage in silicon on insulator devices

(75) Inventors: Mukesh Khare, White Plains, NY (US); Paul D. Agnello, Wappingers Falls, NY (US); Anthony I. Chou, Beacon, NY (US); Terence Blackwell Hook, Jericho Center, VT (US); Anda C. Mocuta, Lagrangeville, NY (US)

Correspondence Address: IBM CORPORATION, 2070 Route 52, Hopewell Junction, NY, 12533, US

(73) Assignee: International Business Machines Corporation, Armonk, NY (US)

(21) Appl. No.: 09/822,453

(22) Filed: Mar. 30, 2001

(51) Int. Cl. H01L 21/00; H01L 21/84; H01L 27/01

(52) U.S. Cl. 438/152; 438/155; 257/347

(57) ABSTRACT

An SOI circuit configuration effective for minimizing plasma-induced charging damage during fabrication comprises the formation of charge collectors connected to the gate electrode and the semiconductor body, wherein each one of the charge collectors have the same or substantially the same shape and dimension. A connecting structure formed between a device fabricated on SOI substrate and substrate is delayed until the latter stages of processing.

### BACKGROUND OF THE INVENTION

The present invention relates generally to semiconductor devices and methods for the manufacture thereof In particular, the invention relates to methods and circuit configurations effective for reducing plasma induced damage on devices fabricated on silicon-on-insulator (SOI) substrates.

Increasing interest in the design and fabrication of ultra large scale integration (ULSI) chips requires a detailed understanding of the modes of plasma charging damage during their fabrication, as well as designs effective in minimizing such damage. A particular concern is plasma-related damage of gate oxides in metal oxide semiconductor (MOS) devices during fabrication. In bulk silicon processes, plasma charge is collected at the gate terminal only since this is the only node with respect to the wafer bulk. The use of protective diodes connected between the gate and the substrate can effectively protect against these type of charging effects. However, in SOI technology, the presence of a buried oxide layer causes both the diffusion and gate nodes to float with respect to the bulk. During plasma processing of SOI wafers, the gate and source/drain antenna can charge to different voltages depending upon their antenna characteristics and may result in tunneling current through the gate oxide, thereby damaging the gate oxide. Moreover, since both the gate and source/drain antenna can charge during plasma mediated processing, the use of protective diodes in SOI circuit configurations is not a practical solution.

### BRIEF SUMMARY OF THE INVENTION

An SOI circuit configuration effective for minimizing plasma-induced charging damage during fabrication, the SOI configuration includes a gate electrode, a semiconductor body having a source diffusion region and a drain diffusion region, and charge collectors connected to the gate electrode and the semiconductor body, wherein each one of the charge collectors have the same or substantially the same shape and dimensions. Such configuration reduces the effect of plasma charging during fabrication by rendering the circuits inherently robust against plasma damage effects.

In another embodiment, the inventors hereof have accordingly recognized that the charge accumulated by a S/D antenna in a device on an SOI wafer can have either positive or negative polarity, and that more damage is observed where a positive antenna is connected on one terminal and a negative antenna is connected to the other terminal than where antenna of the same polarity are connected to each terminal. According to this embodiment, the SOI configuration includes a gate electrode, a semiconductor body having a source diffusion region and a drain diffusion region, and a plurality of contacts connected to selected ones of the gate electrode and the semiconductor body, The contacts are formed by a plasma mediated process effective to impart a positive charge. A plurality of interconnects are in communication with the contacts, wherein the interconnects are formed by a plasma mediated process effective to impart a negative charge. Preferably, the contracts have a narrower width dimension than the interconnects. The SOI configuration reduces plasma induced charging damage.

In another embodiment, the SOI configuration includes a substrate, a buried oxide layer deposited on the substrate, a conductive contact formed in the buried oxide layer and in communication with the substrate and a connecting structure formed between a device fabricated over the buried oxide layer and the conductive contact. The communication between the connecting structure and conductive contact is delayed until a last interconnect level is formed in the device.

A process for the alleviation of plasma-induced damage during SOI wafer fabrication accordingly comprises one or more of: forming charge collectors, wherein each one of the charge collectors has an equal or substantially equal amount of interconnects and contacts connected to the gate electrode or semiconductor; providing equal or substantially equal sizes of interconnects and contacts connected to the gate electrode or semiconductor, or connecting structures between a device and the back side of the substrate situated distant from the substrate so as to delay connection until a last interconnect level is formed in the device.

The methods and SOI configurations will be more fully understood in light of the following detailed description of taken together with the following drawings, which are illustrative, rather than limiting.

### BRIEF DESCRIPTION OF THE DRAWINGS

FIG. 1 is a cross sectional view showing a conventional SOI circuit configuration.

FIG. 2 is a cross sectional view showing various via and interconnect configuration used in device fabrication.

FIG. 3 is a top down view showing various via and interconnect configurations used in device fabrication.

FIG. 4 is a top down view showing an unbalanced amount of vias or interconnects on a semiconductor body and gate electrode.

FIG. 5 is a top down view showing an balanced amounts of vias or interconnects on a semiconductor body and gate electrode in accordance with one embodiment of the invention. FIGS. 6A and B are cross-sectional and top down views of a conventional design that exhibits plasma induced charging damage.

FIGS. 7A and B a cross-sectional and top down views of an improved design for an integrated circuit wherein the vias on both the gate electrode and semiconductor body are similarly sized in accordance with one embodiment of the present invention.

FIGS. 8A and B are cross-sectional and top down views of a conventional design that exhibits plasma induced charging damage.

FIGS. 9A and B are cross-sectional and top down views of an improved design for an integrated circuit wherein the vias on both the gate electrode and semiconductor body are similarly sized in accordance with one embodiment of the present invention.

FIGS. 10A and B are cross-sectional and top down views of a conventional design that is prone to plasma induced charging damage.

FIGS. 11A and B are cross-sectional and top down views of an improved design for an integrated circuit wherein the vias on both the gate electrode and semiconductor body are similarly sized in accordance with one embodiment of the present invention.

FIG. 12 is a schematic diagram of an SOI transistor connected to a substrate by a contact which cuts through the buried oxide layer.

FIG. 13 is a schematic diagram of an SOI transistor wherein connecting structure with a buried contact in the buried oxide layer is placed at an upper metal layer in accordance with one embodiment of the present invention

FIG. 14 is a shown gate leakage current distribution for reference devices, floating antenna SOI devices, and SOI antenna devices.

FIG. 15 is a breakdown voltage histogram of SOI antenna devices with and without connection to the back substrate.

### DETAILED DESCRIPTION OF THE INVENTION

The design of SOI circuit configurations that are inherently robust to plasma damage during fabrication first requires an understanding of the mechanisms by which such damage arises. It is well known that devices fabricated on bulk silicon wafers (as opposed to SOI circuit configurations) can be damaged by the accumulation of charge on the gate antenna. The charge and damage arises from plasma charging and the corresponding flow of high gate current through the gate oxide. Diffusion terminals of all devices are electrically connected to the bulk silicon wafer substrate through p-n junctions, and consequently, the diffusion terminals may not deviate substantially from the substrate potential. A potential difference between the local plasma and the substrate can cause high current flow though the gate oxide. Damage to the gate oxide is caused by a current flux that approaches the charge-to-breakdown (Qbd) limit.

In contrast, SOI circuit configurations include a buried oxide layer between the back substrate and the device body, thereby preventing a direct current path from the device to the bulk. The use of the buried oxide layer results in a device wherein the gate, source/drain regions and the body terminal are all isolated with respect to the wafer bulk, i.e., the gate and the S/D (source/drain) diffusion antenna are floating. During plasma processing of these SOI circuit configurations, the gate and S/D antenna act as charge collectors and can charge to different voltages depending upon the collector characteristics. As the collected charge approaches the Qbd limit, the gate oxide may be damaged by the resulting tunneling current through the gate oxide.

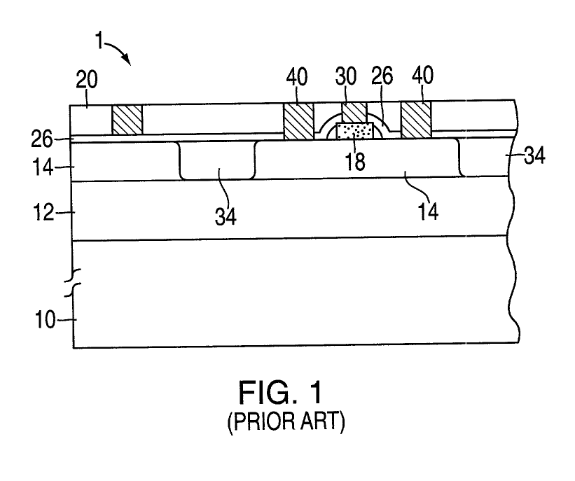

Referring now to the drawings and in particular FIG. 1, there is shown a conventional SOI circuit configuration generally designated by reference numeral 1. The SOI circuit includes a includes a silicon substrate 10 and au oxide layer 12 deposited above substrate 10. A silicon layer 14 is deposited above oxide layer 12, hence the term, “buried oxide layer”. Silicon layer 14 includes at least one shallow trench 34 extending through silicon layer 14 to electrically separate active regions within silicon layer 14 from one another. These active regions typically include transistors or the like formed in silicon layer 14. Trenches 34 are typically filled with an insulative oxide material.

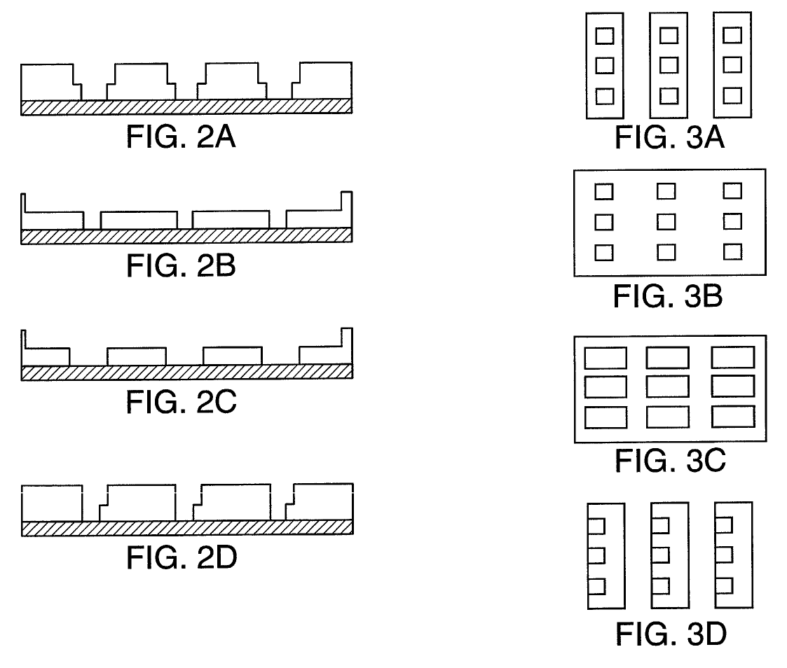

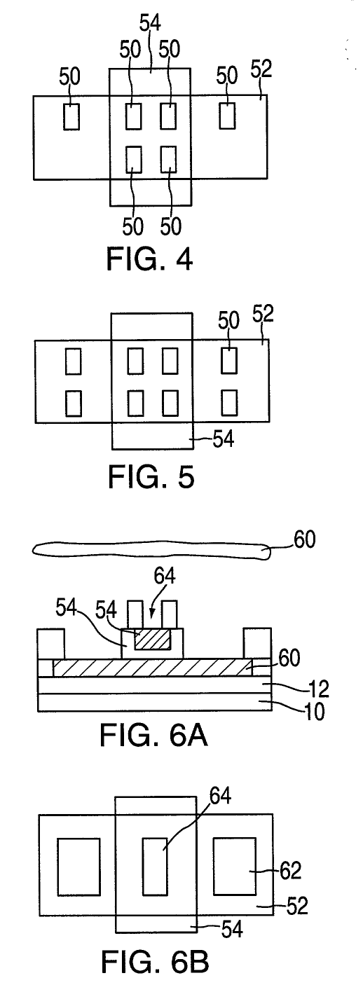

A gate 18 is deposited above silicon layer 14. A passivation layer 26 is deposited above silicon layer 14 and around gate 18. A barrier material 20 is deposited above passivation layer 26. Barrier material 20 is typically a dielectric material such as phosphosilicate glass (PSG), BPSG, nitride, or other similar material. Gate metal contact 30 is deposited above gate 18, as illustrated in FIG. 1, such that gate metal contact 30 extends from the top of SOI chip 1 through barrier material 20 and passivation layer 26 to form an electrical contact with gate 18. Second and third metal contacts 40 are then deposited above silicon layer 14, as illustrated in FIG. 1, such that metal contacts 40 extend from the top of SOI chip 1 through barrier material 20 and passivation layer 26 to form electrical contacts with selected areas of silicon layer 14. FIGS. 2 and 3 show cross-sectional and corresponding top down views illustrating various contacts (or vias) and interconnect configurations commonly practiced in device fabrication. As shown, the contacts or interconnects can have various widths and heights depending on the circuit design. The inventors have discovered that the design and configurations of the contacts or interconnects in SOI circuit configuration are important for minimizing plasma induced charging damage.

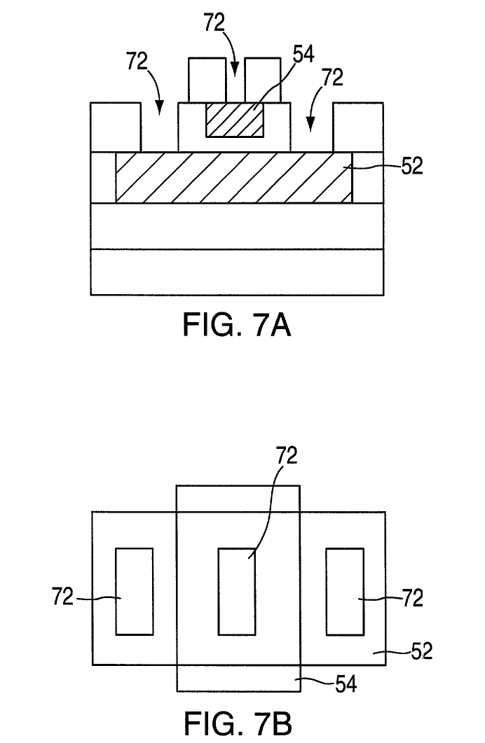

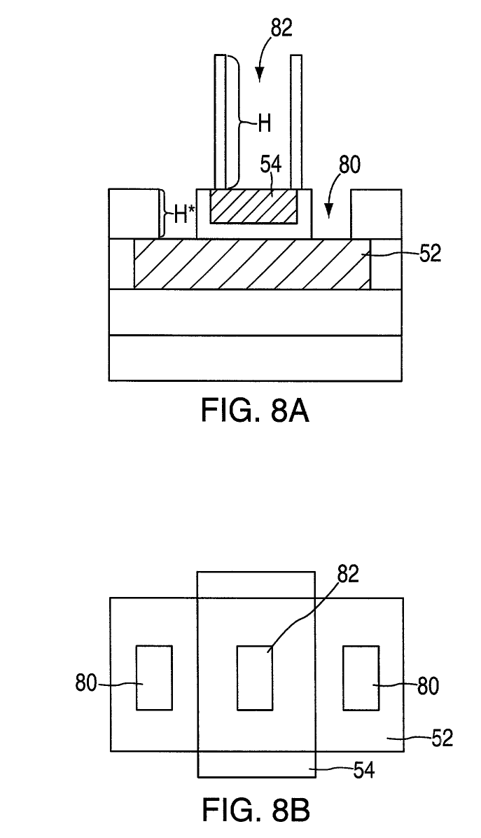

It has been found that plasma induced charging damage can occur in SOI circuit configurations wherein unequal amounts of contacts or interconnects are formed on the semiconductor body and gate electrode. For example, as shown in FIG. 4, an SOI circuit configuration wherein the contacts or interconnects 50 are in unequal amounts in the manner shown, plasma induced charging damage of the gate oxide was observed. In this particular design, the total amount of contacts or interconnects on the gate electrode 54 are greater than the total amount of contacts or interconnects formed on the semiconductor body 52 (four contacts or interconnects formed on the gate electrode 54 versus two contacts or interconnects formed on the semiconductor body 52). Moreover, since the “extra” contacts or interconnects formed on the gate electrode (the lower contacts or interconnects as shown in FIG. 4) are not matched with or aligned with an additional contact or interconnect on the semiconductor body, results in charging damage during plasma mediated processing. In contrast, in a SOI circuit configuration that had equal amounts of contacts or interconnects 50 in the manner shown in FIG. 5, no plasma induced charging damage was observed. That is, the charge-to-breakdown (Qbd) limit was not reached during processing steps such as plasma-mediated dielectric and metal etching, sputtering, dielectric deposition, and the like. Thus, charge imbalances (and thus current conduction through the gate oxide) are alleviated or avoided in SOI circuit configurations that have equal amounts of contacts or interconnects formed on the semiconductor body and the gate electrode.

FIGS. 6A and B show cross-sectional and top down views of a circuit configuration on an SOI wafer that exhibits plasma induced charging damage. Exposing the SOI configuration to a plasma 60 results in charging induced damage. It has been found that the different sizes of contact or interconnect make the fabrication of the device prone to plasma induced charging damage. In this particular example, the contacts or interconnects 62 on the semiconductor body 52 are shown with a wider dimension than the contact or interconnect 64 on the gate electrode 54. It has been found that plasma induced charging damage has a greater propensity to occur compared to devices where the contacts or interconnects have equal or substantially equal sizes. Likewise, it is expected that if the contacts or interconnects on the semiconductor body are smaller in width than the width of the contacts or interconnects on the gate electrode, conditions for charge imbalance exist and as such, plasma induced charging damage may occur during plasma mediated processing.

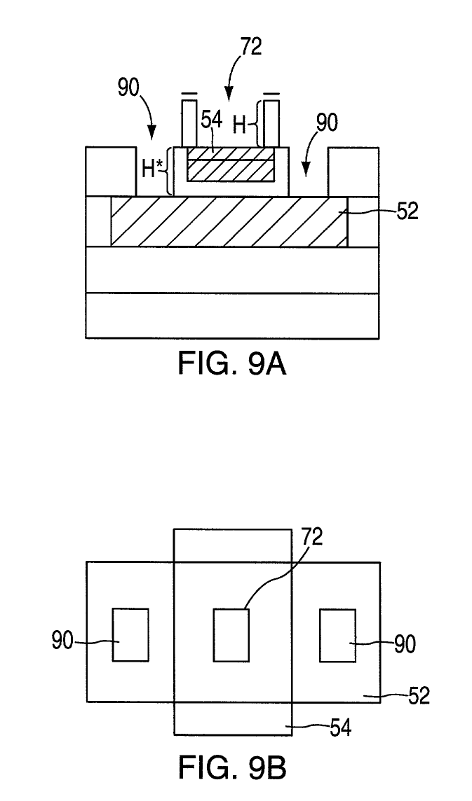

In accordance with one embodiment of the invention, FIGS. 7 A and B show cross-sectional and top down views of a circuit configuration on an SOI wafer that minimizes or eliminates plasma induced charging damage. As shown, the size of the contacts or interconnects 72 on the semiconductor body 52 and the gate electrode 54 are the same. To improve the resistance to plasma induced charging damage, it is preferred that in addition to the same or substantially the same sizes of contacts or interconnects, the total amounts of contacts or interconnects on the semiconductor body equal the total amount of contacts or interconnects on the gate electrode.

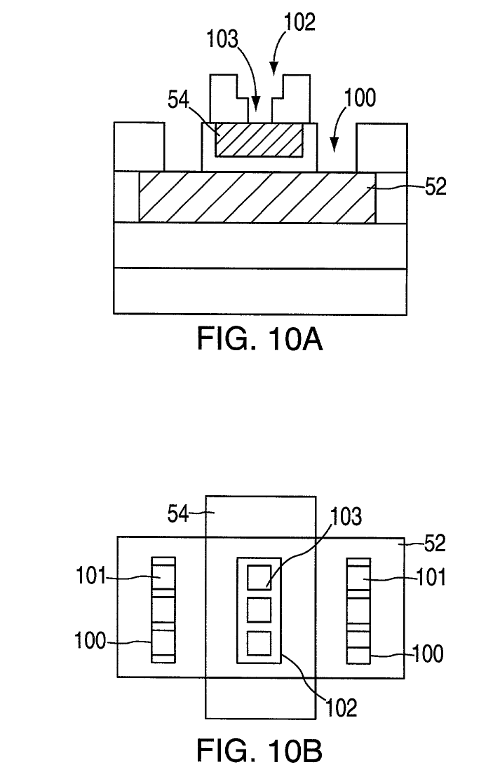

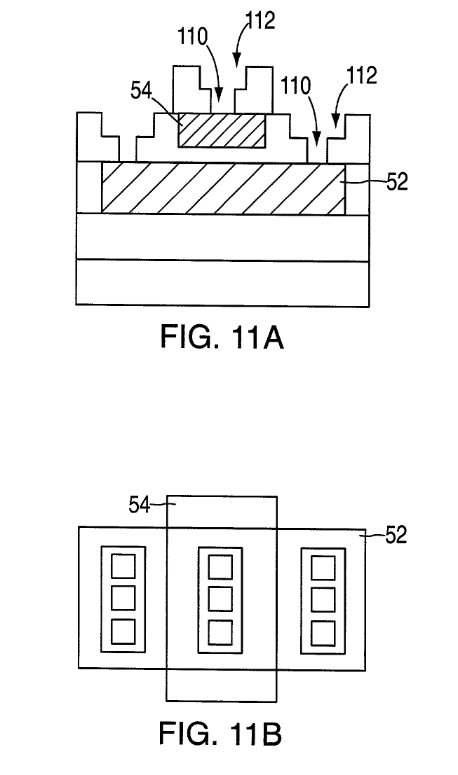

FIGS. 8 A and B show cross-sectional and top down views of a circuit configuration on an SOI wafer that have a propensity to incur plasma induced charging damage during plasma mediated processing steps. As shown, the height dimension II for the contact or interconnect 82 on the gate electrode 54 is different from the height dimension H* for the contacts or interconnects 80 formed on the semiconductor body 52. In contrast, as shown in FIGS. 9A and B, an SOI circuit configuration wherein the height dimension H for all of the contacts or interconnects 90, 92 formed on the semiconductor body 52 and gate electrode 54 are equal to or substantially equal, no plasma induced charging is observed.

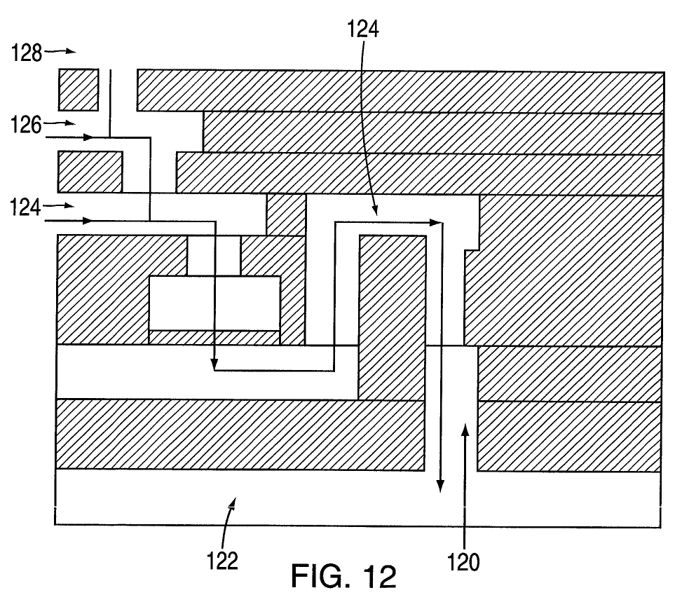

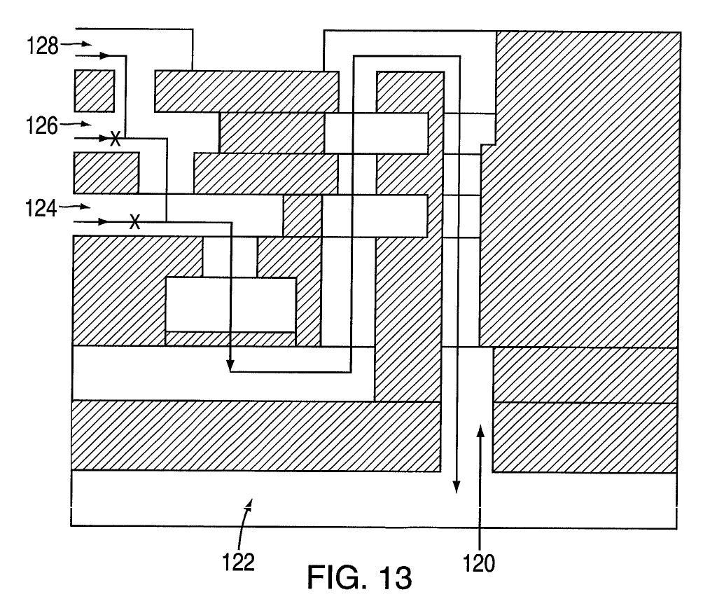

Turning now to FIGS. 10 and 11, there is shown circuit configurations on SOI wafers that demonstrate the effect caused by the dimensional differences in interconnect. In FIGS. 10A and B, the interconnects 100 on the semiconductor body 52 are narrower that the interconnects 102 formed over the gate electrode 54 have different sizes whereas the contacts or vias are the same size on the gate electrode and the semiconductor body. As illustrated, the interconnects 100 formed over the semiconductor body have the same width as the underlying contacts 101. A charge imbalance may occur during plasma mediated processing under these conditions. In contrast, as shown in FIGS. 11 A and B, plasma induced charging damage is not observed where the dimensions of the contacts 110 and interconnects 112 on both the gate electrode 54 and semiconductor body 52 are equal or substantially equal to each other respective contact or interconnect. Although the contacts and interconnects are shown in combination as an inverted T shape, it is expected that similar results will be obtained for other shapes, e.g., an inverted L shape, as long as each respective contact or interconnect has equal or substantially equal dimensions.

Plasma induced charging damage on SOI wafers is minimized or eliminated by employing some or all of the above noted design configurations. Preferably, the amounts and size dimensions of the contacts or interconnects formed on the semiconductor body and gate electrode are the same or substantially the same. However, it is not necessary that the interconnects relative to the contacts be of the same or substantially the same dimension and vice versa. Preferably, each of the interconnects formed are of the same or substantially the same dimension and likewise, all of the contacts formed should be the same or substantially the same dimension, regardless of their node connection, i.e., the semiconductor body or gate electrode.

In accordance with another aspect of improved SOI design, the SOI circuit configuration is designed so as to ensure that the charge collectors have the same polarity. The inventors hereof have further recognized that the charge accumulated by antenna in a device on an SOI wafer can have either positive or negative polarity depending upon the dimension of the structure etched in the plasma process. A plasma etch of a structure having large dimensions generally causes accumulation of a negative charge in the collection areas, whereas an etch of a structure having very small dimensions generally accumulates a positive charge on the antenna. Greater plasma induced charging damage is observed where a positive antenna is connected on one terminal and a negative antenna is connected to the other terminal, than where antenna of the same polarity are connected to each terminal. In accordance with one aspect of an improved SOI design, SOI circuit configurations are designed so as to provide equal-sized contacts (or vias) or interconnects connected on both the gate electrode and semiconductor, for example as previously shown in FIGS. 7 and 9. Such design results in both the gate and semiconductor body being equally positively charged, alleviating or preventing a voltage difference and thus current flow that can damage the circuit. Accordingly, it is preferred to have narrow contacts or vias and a wide interconnect in communication with the contacts or vias.

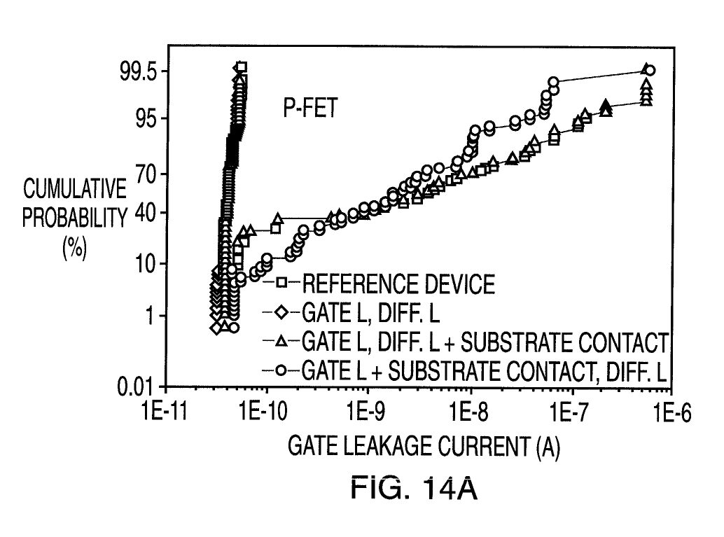

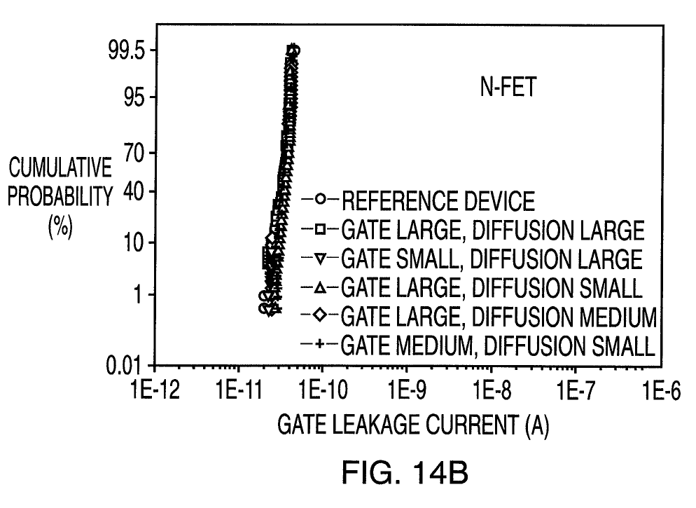

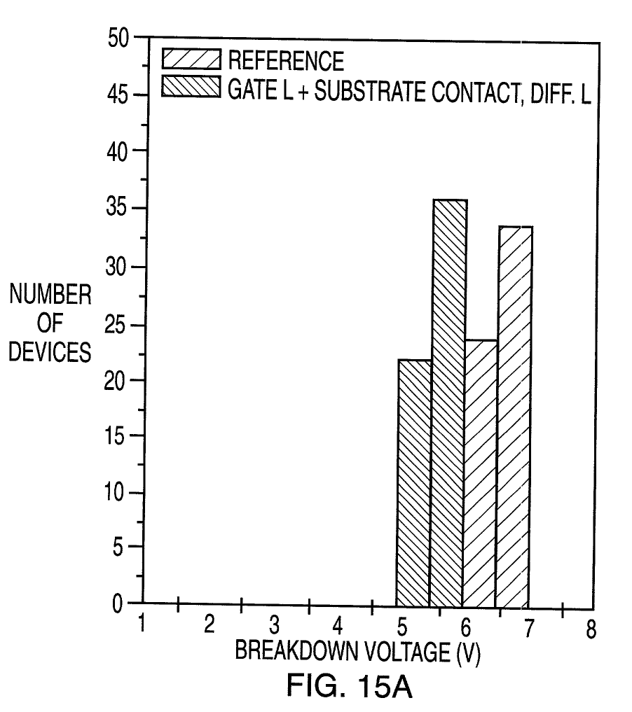

Charging damage may also arise where devices are not isolated from the buried substrate. As shown schematically in FIGS. 12 and 13, an SOI transistor is commonly connected to the substrate by a contact which cuts through the buried oxide layer. Connection thus provides an additional charge path through the gate electrode, the gate oxide, and into substrate. As shown in FIG. 12, where the device is connected to the substrate by forming the contact in the lower metal levels, for example forming a buried contact 120 to the substrate 122 in lower metal level 124, charging damage occurs at all metal levels 126, and 128 at and above metal level 126. The inventors hereof have adduced direct experimental evidence that MOS (metal oxide semiconductor) devices on SOI wafers electrically connected to the back side of the substrate during fabrication are more prone to plasma-related damage. In order to simulate bulk silicon charging conditions on SOI wafers, structures were fabricated with the gate and the diffusion terminals selectively connected to the back side silicon substrate. These connections were created by etching through the buried oxide and filling it with highly doped polysilicon before all metal and via processes. A device with large antennas to both the gate and the diffusion terminals that showed no charging damage when floating in contact was heavily damaged when either the S/D diffusion node or gate node was connected to the back of the substrate (FIGS. 12 and 14).

As shown in FIG. 13, a strategy to alleviate or prevent plasma-related damage during fabrication therefore comprises delaying making any electrical connections of devices through buried oxide to the back side of the substrate until as late as possible in processing, and preferably as the last step of processing. For example, as shown schematically in FIG. 13, by making the buried contact 120 to substrate 122 to the device at an upper metal layer (for example, metal layer 128), charging damage of the lower metal layers 124 and 126 is minimized because the device is not connected until metal layer 128, and no current can flow during upper metal layer processing. Formation of interlevel contacts 120 until as late as possible in processing thus ensures that no electron pathways are formed which can result in damage during application of plasma mediated processes.

The invention is further illustrated by the following non-limiting examples.

### EXAMPLES

### Example 1

Bulk silicon wafers were processed together with SOI wafers in the same lot using the same mask set. All the antenna structures were flow with polysilicon, local interconnect, seven metal and all the via stack finger type structures with minimum allowed pitch and are connected by via antenna arrays of minimum allowed via dimensions to evaluate the worst case charge damage. The test structures were both P-MOS and N-MOS transistors of 0.3 micron×20 micron and 0.18 micron×20 micron dimensions with gate oxide thickness in the range from 2.0 to 2.5 nananometers.

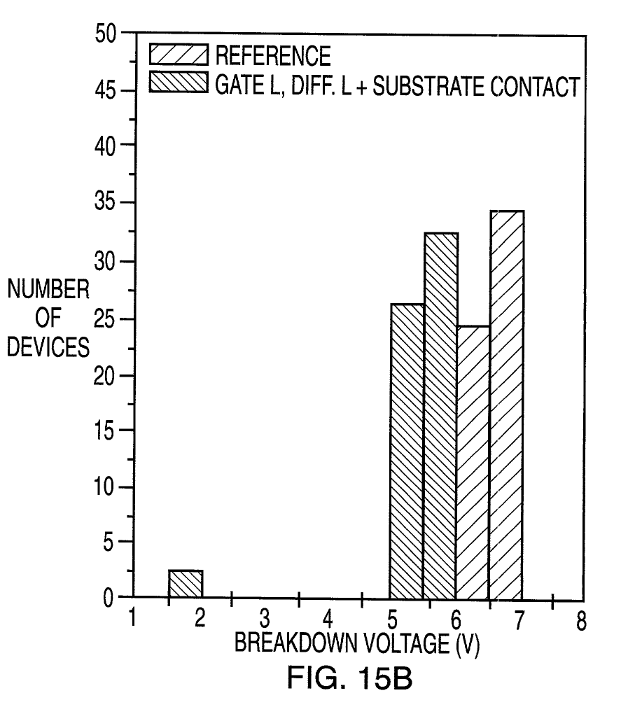

Measurement of gate leakage current and the time-dependent dielectric breakdown (TDDB) are effective means for showing plasma charging damage in 2.0 to 2.5 nm gate oxides. FIG. 15 illustrates the differences in gate leakage current distribution between bulk silicon and SOI devices with large classical antenna configurations (gate antenna only). This plot clearly shows that the SOI devices are substantially more robust against plasma charging damage compared to those on the bulk silicon wafer, even those wafers with protective diodes.

### Example 2

In order to simulate bulk silicon charging conditions on SOI wafers, structures were fabricated with the gate and the diffusion terminals selectively connected to the back side silicon substrate. These connections were created by etching through the buried oxide and filling it with highly doped polysilicon before all metal and via processes. A device with large antennas to both the gate and the diffusion terminals showing no charging damage when floating was heavily damaged when either the S/D diffusion node or gate node was connected to the back of the substrate (FIGS. 12 and 14).

### Example 3

Via antennas and via bar antennas were connected to the gate and diffusion terminal of the transistors. It was found that via antennas charge more positively than via bar antennas and results in damage to the gate oxide.

### Example 4

Antennas with vias of identical size but leading to interconnect wires of different sizes can charge to different potentials. Antennas of the same antenna ratio and via size but connecting to different wire widths were attached to the gate and diffusion of transistors. The antenna device showed significant oxide damage during plasma processing.

### Example 5

The antennas with vias of the same size and leading to interconnects of the same size can charge to different potential depending on the positioning of the vias under the interconnect (center vs. edge). The antenna with centered vias charged to a less positive potential than the antenna with vias at the edge of the interconnect resulting in gate oxide damage during plasma processing.

While preferred embodiments have been shown and described, various modifications and substitutions may be made thereto without departing from the spirit and scope of the invention. Accordingly, it is understood that the present invention has been described by way of illustrations and not limitation.

What is claimed:

1. An SOI circuit configuration effective for minimizing plasma-induced charging damage during fabrication, the SOI configuration comprising:
a gate electrode;
a semiconductor body having a source diffusion region and a drain diffusion region; and
charge collectors connected to the gate electrode and the semiconductor body, wherein each one of the charge collectors has the same or substantially the same shape and dimensions.

2. The SOI circuit configuration of claim 1, wherein the total number of charge collectors on the gate electrode is equal to the total number of charge collectors on the semiconductor body.

3. The SOI circuit configuration of claim 1, wherein each one of the charge collectors comprises a contact and a portion of an interconnect in communication with the contact, wherein a cross-section of each charge collector is the same or substantially the same as another charge collector.

4. The SOI circuit configuration of claim 3 wherein a cross section of the contact for the charge collectors is the same or substantially the same.

5. The SOI circuit configuration of claim 3, wherein each one of the contacts for each charge collector has the same dimension and shape or substantially the same dimension and shape, and wherein the interconnect has a width dimension that is wider than a width dimension of the contact.

6. The SOI circuit configuration of claim 3 wherein each one of the interconnects for the charge collectors have the same shape and dimension.

7. An SOI circuit configuration effective for the alleviation of plasma-induced damage during fabrication comprises:
a gate electrode;
a semiconductor body having a source diffusion region and a drain diffusion region;
a plurality of contacts connected to selected ones of the gate electrode and the semiconductor body, wherein the contacts are formed by a plasma mediated process effective to impart a positive charge; and
a plurality of interconnects in communication with the contacts, wherein the interconnects are formed by a plasma mediated process effective to impart a negative charge.

8. The SOI circuit configuration of claim 7, wherein portions of the interconnects are in communication with the contacts, and wherein each contact is at the same or substantially the same relative position with respect to each of the interconnects.

9. The SOI circuit configuration of claim 7, wherein the interconnects have a width dimension that is wider than a width dimension for the contacts.

10. An SOI circuit configuration effective for minimizing plasma-induced charging damage during fabrication, the SOI configuration comprising:
a substrate;
a buried oxide layer deposited on the substrate;
a conductive contact formed in the buried oxide layer and in communication with the substrate; and
a connecting structure formed between a device fabricated over the buried oxide layer and the conductive contact, wherein the communication between the connecting structure and conductive contact is delayed until a last interconnect level is formed in the device.

11. A process fur reducing charging damage during a plasma-mediated process while fabricating integrated circuits on SOI wafers comprises one or more of:
forming charge collectors, wherein each one of the charge collectors has an equal or substantially equal amount of interconnects and contacts connected to the gate electrode or semiconductor;
providing equal or substantially equal sizes of interconnects and contacts connected to the gate electrode or semiconductor; or
connecting structures between a device and the back side of the substrate situated distant from the substrate so as to delay connection until a last interconnect level is formed in the device.
